(19) United States
(12) Patent Application Publication
(10) Pub. No.: US 2006/0097220 A1
(43) Pub. Date: May 11, 2006

(54) Etching solution and method for removing low-k dielectric layer

(75) Inventors: Mi-Young Kim, Suwon-si (KR); Hyo-San Lee, Suwon-si (KR); Uk-Sun Hong, Seongnam-si (KR); Jun-Hwan Oh, Incheon-si (KR); Sang-Min Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/270,339

(22) Filed: Nov. 9, 2005

(30) Foreign Application Priority Data
Nov. 10, 2004 (KR) 2004-91503

(51) Int. Cl. C09K 13/00; B44C 1/22; H01L 21/461

(52) U.S. Cl. 252/79.1; 252/79.3; 252/79.4; 216/83; 438/745

(57) ABSTRACT

Etching solutions are disclosed for etching low-k dielectric layers on substrates, said solutions including effective proportions of an oxidant for oxidizing a low-k dielectric layer and effective proportions of an oxide etchant for removing oxides. It is possible to easily remove a low-k dielectric layer using such etching solutions by a single-stage treatment process.

### CROSS-REFERENCE TO RELATED APPLICATIONS

This U.S. non-provisional patent application claims priority under 35 U.S.C. § 119 of Korean Patent Application 2004-91503 filed on Nov. 10, 2004, the entire contents of which are hereby incorporated by reference.

### BACKGROUND OF THE INVENTION

The present invention relates to fabrication of a semiconductor element, and more particularly to etching solutions for etching a low-k dielectric layer and to related methods of etching a low-k dielectric layer using the same.

In processes of fabricating a semiconductor integrated circuit, an insulating material such as SiO₂ is commonly used for performing electrical isolation and insulation, or for insulating a conductive structure (such as a metal wiring line) that constitutes at least a portion of a semiconductor integrated circuit from other adjacent conductive structures. However, because an ever higher degree of integration is being required for the processes of fabricating current semiconductor integrated circuits, the distances between metal wiring lines that are vertically and horizontally adjacent to each other is gradually being reduced. As a result, coupling capacitance, which is caused by adjacent metal wiring lines that are insulated from each other by SiO₂, increases. Such an increase in coupling capacitance in turn results in reduction in the speed of a semiconductor element and an increase in the level of cross-talk. Also, an increase in the coupling capacitance increases the power consumption of the element.

In order to solve such problems, a more effective method of electrically isolating and insulating metal wiring lines from each other using a low-k dielectric material having a lower dielectric constant than SiO₂ is desired. SiOₓ doped with a carbon component (including Carbon itself) is widely used as such a low-k dielectric material. In such a doped SiO₂, at least a part of an Oxygen atom that is coupled with Silicon is at least partially displaced by a carbon component, such as an organic substance group, and including Carbon itself. A silicon oxide doped with an organic Carbon component is referred to hereinafter as organo-silicate glass (OSG). Such OSG materials are commonly formed by a chemical vapor deposition method using organo-silane and organo-siloxane.

On the other hand, in the processes of fabricating a modern, high-performance semiconductor integrated circuit, in order to control process quality, various test processes are performed after a specific process, and it is desirable to be able to reuse the wafer used for the test process after the test. In particular, since the diameters of such wafers have recently increased making them more expensive, an important cost-saving issue is to be able to re-use these expensive wafers.

In order to be able to re-use a wafer, a film formed on the wafer for the test process typically must be removed. Such film removal generally includes a wet etching method in which proper chemicals are used, or, alternatively, a chemical mechanical polishing (CMP) method in which slurry is used. However, since the CMP method includes more complicated process steps, results in lower yield than the wet etching method, and requires a more difficult batch wafer process than the wet etching method, the wet etching method is generally preferred.

However, as is well known, a low-k dielectric layer formed of Silicon-Oxygen-Carbon has the properties of being generally hydrophobic. Therefore, since the low-k dielectric layer is not wetted at all by deionized water, and is hardly wet-etched by other chemicals, the test wafer on which a low-k OSG dielectric layer has been formed often cannot be re-used but is instead abandoned.

U.S. Pat. No. 6,693,047 issued to Lu, which is incorporated herein by reference, discloses a method of re-using the wafer on which a low-k dielectric layer has been formed. According to the method disclosed in U.S. Pat. No. 6,693,047, the wafer on which the low-k dielectric layer has been formed is furnace-oxidized or plasma oxidized to remove the Carbon component. The oxidized portion of the film is then removed using an oxide film wet etching solution. In U.S. Pat. No. 6,693,047, however, because the oxidation process and the wet-etching process are performed as separate steps, the combination of these processes is not economical. Also, in U.S. Pat. No. 6,693,047, since furnace oxidation or plasma oxidation is adopted as the oxidation process, it takes a relatively long time to perform such oxidation, which is disadvantageous to economical operation and to productivity. Therefore, a new technology of etching a low-k OSG or comparable dielectric layer on a test wafer or the like is required.

### SUMMARY OF THE INVENTION

Accordingly, it is a general object of the present invention to provide etching solutions for removing a low-k dielectric layer (such as an OSG layer) from a wafer and etching methods using the same.

In order to achieve the above object, according to embodiments of the present invention, there is provided etching solution for removing a low-k dielectric layer. It is possible with the present invention to etch the low-k dielectric layer by performing a single-step etching process using such etching solution.

Etching solutions for the low-k dielectric layer according to the embodiments of the present invention include an effective proportion of an oxidant in combination with an effective proportion of an oxide etchant. It is believed that the oxidant in the etching solution oxidizes the low-k dielectric layer to form an SiOₓ material. On the other hand, it is believed that the oxide etchant then substantially simultaneously removes (strips) the SiOₓ material.

More specifically, according to the present invention, when the wafer on which a SiOC-based low-k dielectric layer is formed contacts the washing (etching) solution according to the present invention, oxidation and fluorination continuously occur such that the low-k dielectric layer is effectively and relatively quickly removed from the wafer.

The low-k dielectric layer for which the etching solutions and etching methods of the present invention have been found useful is not limited to the above-described OSG dielectric layers. For example, it has been found that trimethylsilane (TMS) (available under the tradename BLACKDIAMOND™), tetramethylcyclotetrasilane (TMCTS) (available under the tradename Coral™), dimethyldimethoxysilane (DMDMOS) (available under the tradename Aurora™), hydrogen silsesquioxane (HSG), fluorinated poly arylene ether (FLARE), Xerogel, erogel, Parylene, Polynaphthalene, a material available under the tradename SiLK™, MSQ, BCB, Polyimide, Teflon, and amorphous fluorinated carbon may each be used as the low-k dielectric layer with excellent etching results.

For example, if the low-k dielectric layer is one including Silicon, Oxygen, and Carbon (or a silicon oxide layer doped with Carbon) (hereinafter referred to as a SiOC dielectric layer), the oxidant is believed to oxidize the SiOC dielectric layer to form an SiOₓ material and to remove the organic matter group including Carbon. On the other hand, the oxide etchant removes the SiOₓ material in a step wherein SiOₓ is fluorinated to volatile materials such as SiF_{w} and H_{y}SiF_{z} (wherein w, y, and z are positive integers) by the oxide etchant and thereby effectively removed from the surface of the wafer.

According to an embodiment of the present invention, in order to improve the wettability of a generally hydrophobic low-k dielectric layer, for example an OSG layer, the etching solution of this invention may further comprise an effective proportion of a surfactant. The surfactant is selected to be effective in changing the generally hydrophobic low-k dielectric layer into a generally hydrophilic low-k dielectric layer. As a result, the etching ratio of the etching solution including the surfactant will preferably increase relative to a comparable etching solution without the surfactant.

The oxidant used in the low-k dielectric layer etching solution of the present invention is not limited to one particular material. For example, H₃PO₄, HNO₃, H₂SO₄, HClO₄, HClO₂, H₂O₂, NaOCl, ClO₂, CH₃COOOH (Peracetic acid: PAA), and O₃, or a mixture of two or more of the above materials may be used as the oxidant. CH₃COOOH (Peracetic acid: PAA) is a preferred oxidant for certain invention embodiments.

CH₃COOOH (Peracetic acid: PAA) is easily prepared by mixing CH₃COOH with H₂O₂, and it is also relatively inexpensive as a reagent.

The oxide etchant used in the low-k dielectric layer etching solution of the present invention is not limited to one particular material but rather may include, for example, generally any compatible fluoride-based reducer. HF, HBF₄, and NH₄F, or a mixture of two or more of these materials may be used as the fluoridebased reducer. HF is a preferred oxide etchant for certain invention embodiments. Since HF is widely used for common semiconductor fabrication processes, HF can usually be easily obtained.

Surfactants useful in the etching solutions of the present invention may be selected from nonionic surfactants and ionic surfactants. The group of ionic surfactants includes anionic, cationic, or amphoteric surfactants. The group of anionic surfactants includes but is not limited to potassium perfluoroalkyl sulfonate and amine perfluoroalkyl sulfonate. The group of cationic surfactants includes but is not limited to fluorinated alkyl quarternary ammonium iodides. The group of amphoteric surfactants includes but is not limited to fluoroalkyl sulfonate and sodium salt. The group of nonionic surfactants includes fluorinated alkyl alkoxylates, fluorinated polymeric esters, and a material identified as NCW1002® sold by Wako Chemical Company.

According to an embodiment of the present invention, there is provided a method of removing a low-k dielectric layer from a semiconductor wafer using a low-k dielectric layer etching solution as defined herein. According to one method of removing the low-k dielectric layer, the wafer on which the low-k dielectric layer is formed contacts the low-k dielectric layer etching solution by dipping the wafer into the etching solution for an effective period of time. When the temperature of the etching solution is raised above room temperature, the etching ratio increases. For example, a preferred temperature of the etching solution used for treating a wafer in accordance with this invention is in the range of about 25° C. to about 80° C.

### BRIEF DESCRIPTION OF THE DRAWINGS

The accompanying drawings are included to provide a further understanding of the invention, and are incorporated in and constitute a part of this specification. The drawings illustrate exemplary embodiments of the present invention and, together with the description, serve to explain principles of the present invention. In the drawings:

FIG. 1 uses a block diagram and a related two-step chemical equation for illustrating processes of etching a SiOC dielectric layer according to the present invention;

FIGS. 2A to 2C illustrate a time sequence of vertical scanning electron microscope (V-SEM) images of a wafer being treated in accordance with the present invention at various dipping times wherein the wafer on which a low-k dielectric layer is formed is dipped into an etching solution according to the present invention at about 25° C.;

FIG. 3 illustrates FT-IR spectrums taken before and after dipping a wafer into a low-k dielectric layer etching solution according to the present invention;

FIGS. 4A and 4B illustrate the results of measuring contact angles before and after applying a low-k dielectric layer etching solution according to this invention to a substrate on which a low-k dielectric layer is formed; and

FIGS. 5 to 8 are graphs illustrating the test results of experiment examples 1 to 4 as described hereinafter.

### DETAILED DESCRIPTION OF PREFERRED EMBODIMENTS

Preferred embodiments of the present invention will be described below in more detail with reference to the accompanying drawings. It will be understood, however, that the present invention may be embodied in different forms and should not be construed as limited to the embodiments set forth herein. Rather, these embodiments are provided so that this disclosure will be thorough and complete, and will fully convey the scope of the invention to those skilled in the art.

The present invention relates generally to etching solutions for etching a low-k dielectric layer on a semiconductor substrate and to methods of etching a low-k dielectric layer using the same. In particular, the present invention can be effectively applied to removing a SiOC-based dielectric layer from a semiconductor wafer. Etching of the low-k dielectric layer according to the present invention includes substantially simultaneously performing oxidation and fluorination treatment processes on the low-k dielectric layer using an etching solution according to the present invention. In order to perform oxidation and fluorination, effective proportions of an oxidant and an oxide etchant are used, respectively, to form the etching solution. The oxidant oxidizes the low-k dielectric layer to form an SiOₓ material. At this time, the organic matter group that actually includes Carbon is removed from the low-k dielectric layer in the form of, for example, hydrogenated carbon, that is, a CHₓ material. The oxide etchant fluorinates the SiOₓ material formed as a result of oxidation to remove (strip) SiOₓ from the surface of the wafer. The amounts (proportions in volume %) of the oxidant and the oxide etchant in the etching solution may be varied in consideration of the low-k dielectric layer to be removed and other process parameters.

The oxidant and the oxide etchant may be included for example in the etching solution at a volume ratio ranging from about 1:1 to about 900:1 of oxidant to oxide etchant. More particularly, the low-k dielectric layer etching solution may include the oxidant in a proportion of about 30 through 90 volume %, and it may include the oxide etchant in a proportion of about 0.1 through 30 volume %.

As a more specific example, the low-k dielectric layer etching solution of this invention may include the oxidant in a proportion of about 30 through 90 volume %, the oxide etchant in a proportion of about 0.1 through 30 volume %, and deionized water in a proportion of about 0.1 through 40 volume %.

On the other hand, in invention embodiments wherein a surfactant is included, the surfactant may comprise about 0.05 through about 10% with respect to the total diluted volume of the oxidant and the oxide etchant. That is, the surfactant may be included such that the ratio of the total diluted volume of the oxidant and the oxide etchant to the volume of the surfactant is in the range of about 100:0.05 to about 10:1. When it is not specially mentioned in the present specification, the amount of the surfactant used in an etching solution is a predetermined % with respect to the total diluted volume of the oxidant and the oxide etchant.

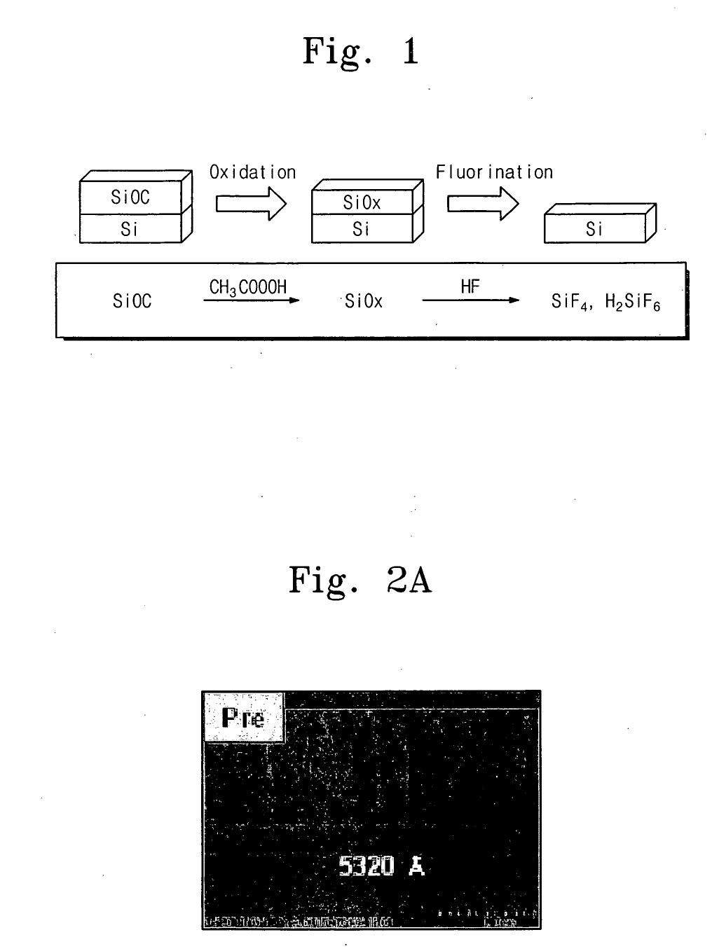

FIG. 1 uses a block diagram and a related chemical equation to illustrate processes of etching a SiOC dielectric layer according to the present invention. Referring to FIG. 1, the silicon wafer (Si) on which the low-k dielectric layer SiOC is formed is dipped into an etching solution including CH₃COOOH as the oxidant and HF as the oxide etchant. At this time, the SiOC dielectric layer is oxidized by the oxidant (such as CH₃COOOH) to an SiOₓ material, and the SiOₓ material is substantially immediately fluorinated to volatile components such as SiF₄ and H₂SiF₆ by the oxide etchant (such as HF) and are thereby stripped from the surface of the silicon (Si) wafer.

In embodiments of the present invention, H₃PO₄, HNO₃, H₂SO₄, HClO₄, HClO₂, H₂O₂, NaOCl, ClO₂, CH₃COOOH (Peracetic acid: PAA), O₃, and mixtures thereof may be used as the oxidant component of the low-k dielectric layer etching solution. For many invention embodiments, CH₃COOOH is preferred as the oxidant. CH₃COOOH is easily obtained by mixing CH₃COOOH with H₂O₂, and it is relatively inexpensive. CH₃COOOH may be diluted with deionized water, such as by up to about 15%, to be used.

The oxide etchant may include, for example, a fluoride-based reducer. HF, HBF₄, NH₄F, and mixtures thereof may be used as the fluoride-based reducer. For many invention embodiments, HF is preferred as the oxide etchant. HF may be diluted with deionized water, such as by up to about 49%, to be used. In another example, a mixture of HF and NH₄F, so-called BOE, may be used as a mixture as the fluoride-based reducer.

(Fabrication of Etching Solution)

Low-k dielectric layer etching solution can be easily prepared by preparing the above-described oxidant and oxide etchant components and mixing them with each other in suitable proportions to achieve a desired solution volume %. Also, in order to improve the moistness (wettability) characteristic of the low-k dielectric layer being treated, a surfactant component may be added, generally calculated as a predetermined % with respect to the total diluted volume of the oxidant and the oxide etchant. A controlled amount of surfactant is added, if desired, so as not to prevent or unduly interfere with etching. Nonionic surfactant or ionic surfactant may be used as the surfactant. Anionic, cationic, or amphoteric surfactant may be used as the ionic surfactant.

(Etching of Low-k Dielectric Layer)

When the etching solution prepared as described above is used, the low-k dielectric layer is easily and rapidly removed by a single treatment process. The low-k dielectric layer is removed from a wafer by simply contacting the wafer on which the low-k dielectric layer is formed with the etching solution. For example, in one contacting method, the etching solution may contact the wafer by dipping the wafer into a tub filled with the etching solution. Furthermore, in order to improve the etching ratio, while the wafer is dipped into the etching solution, the etching solution may be agitated using any suitable fluid agitation method. The dipping method as described is useful for carrying out a batch wafer treatment process. It is also possible, however, to contact the etching solution with the wafer by a spin method. That is, the wafer may be mounted on a rotation table so as to spray the etching solution onto the surface of the wafer. Such spin method is useful in treating a single wafer to economize on the use of the etching solution.

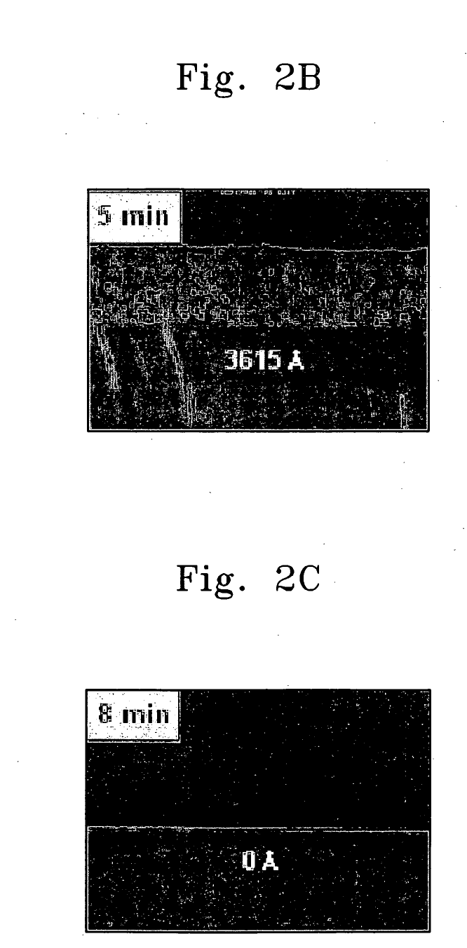

FIGS. 2A to 2C illustrate time sequence vertical scanning electron microscope (V-SEM) images of a wafer being treated in accordance with the present invention at various dipping times wherein the wafer on which the SiOC based low-k dielectric layer is formed is dipped into etching solution according to the present invention at a temperature of about 65° C. The etching solution used here consisted essentially of 90 volume % of CH₃COOOH diluted with water by 15%, 10 volume % of HF diluted with water by 49%, and a nonionic surfactant in the amount of 0.6% by volume with respect to the total volume of diluted CH₃COOOH and diluted HF used. In the present experiment, the wafer initially had a low-k dielectric layer of about 5,320 Å in thickness formed thereon. To begin the treatment method of this invention, the wafer with the dielectric layer was dipped into the etching solution. FIG. 2A is a V-SEM image of the wafer before it was dipped into the etching solution. FIG. 2B is a V-SEM image of the wafer after it had been dipped into the etching solution for a period of five minutes. FIG. 2C is a V-SEM image of the wafer after it had been dipped into the etching solution for a period of eight minutes.

First, referring to FIG. 2B, it can be seen that the low-k dielectric layer after 5 minutes of treatment time is more porous than the low-k dielectric layer of FIG. 2A, and also that the thickness of the low-k dielectric layer has been reduced from 5,320 Å to 3,651 Å. It is believed that this is because an organic matter group including Carbon has been at least partially removed while the low-k dielectric layer is being oxidized by the etching solution. Referring to FIG. 2C, it can be seen that the low-k dielectric layer has been substantially completely removed from the surface of the wafer after a treatment period of only eight minutes.

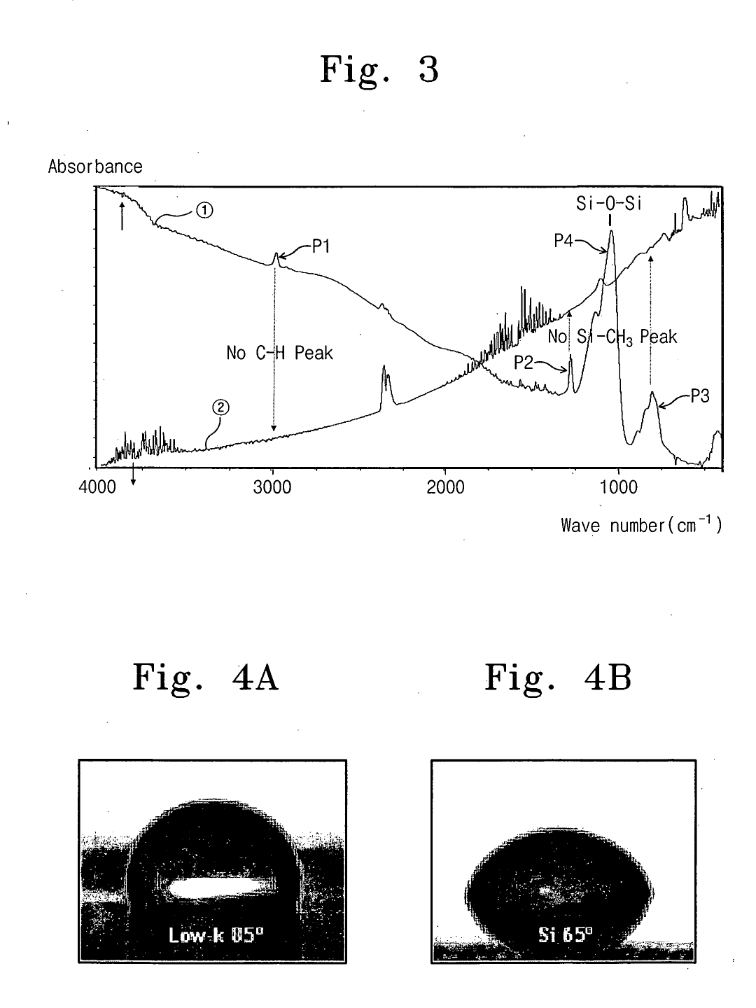

In order to better demonstrate the etching performance of the above-described low-k dielectric layer etching solution, FT-IR spectrums of the wafer before and after applying the etching solution were obtained. FIG. 3 illustrates the FT-IR spectrums before and after dipping the wafer into the etching solution. As described above, the SiOC based low-k dielectric layer was etched using an etching solution consisting essentially of 90 volume % of CH₃COOOH diluted with deionized water by 15%, 10 volume % of HF diluted with deionized water by 49%, and a nonionic surfactant in the amount of 0.6% by volume with respect to the total volume of diluted CH₃COOOH and diluted HF at 65° C. for about eight minutes of treatment time. In FIG. 3, reference numeral P1 denotes the peak of a Carbon-Hydrogen bonding structure, reference numerals P2 and P3 denote peaks of a Si—CH₃ bonding structure, and reference numeral P4 denotes the peak of a Si—O—Si bonding structure. In FIG. 3, spectrum 1 denotes the FT-IR spectrum before applying the etching solution, and spectrum 2 denotes the FT-IR spectrum after applying the etching solution.

Referring to FIG. 3, it can be seen that all of the peaks P1, P2, P3, and P4 are shown in spectrum 1, which means the low-k dielectric layer before applying the etching solution includes the organic matter group including Carbon. On the other hand in spectrum 2, the peak of the C—H bonding structure (represented by P1 in spectrum 1) and the peaks of the Si—CH₃ bonding structure (represented by P2 and P3 in spectrum 1) have been removed; and, the peak of the Si—O—Si bonding structure (represented by P4 in spectrum 1) has been remarkably reduced and hardly shows up at all. That is, it can be seen that the organic matter group including Carbon has been removed, that SiOₓ has been remarkably reduced, and that the low-k dielectric layer has been substantially removed by the change in the chemical structure of the low-k dielectric layer resulting from applying the etching solution.

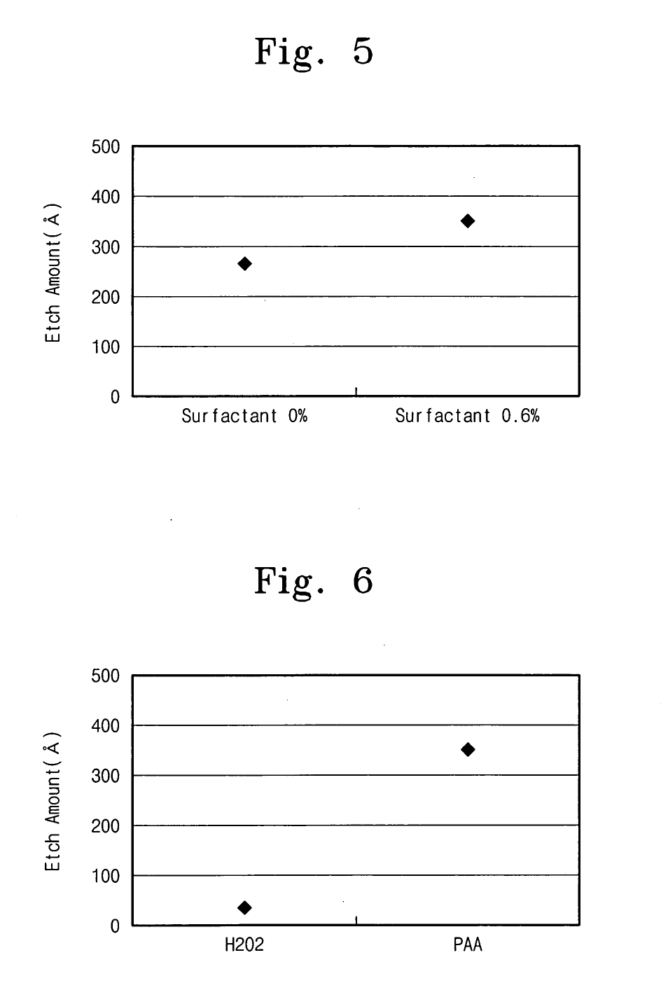

In order to better demonstrate the performance of the low-k dielectric layer etching solution according to the present invention, a contact angle was measured before and after an etching solution treatment. The wafer on which the SiOC based low-k dielectric layer was formed was dipped into the low-k dielectric layer etching solution consisting essentially of 90 volume % of CH₃COOOH diluted with deionized water by 15%, and 10 volume % of HF diluted with deionized water by 49% at 65° C. for about eight minutes. FIGS. 4A and 4B illustrate the results of measuring contact angles before and after applying the low-k dielectric layer etching solution to the substrate on which the SiOC based low-k dielectric layer was formed. As illustrated in FIG. 4A, before applying the etching solution, the contact angle of the substrate was about 85°. However, as illustrated in FIG. 4B, after applying the etching solution, the contact angle of the substrate was only about 65°, which is substantially reduced from the pre-treatment 85° contact angle. This means that the low-k dielectric layer has been substantially removed from the substrate.

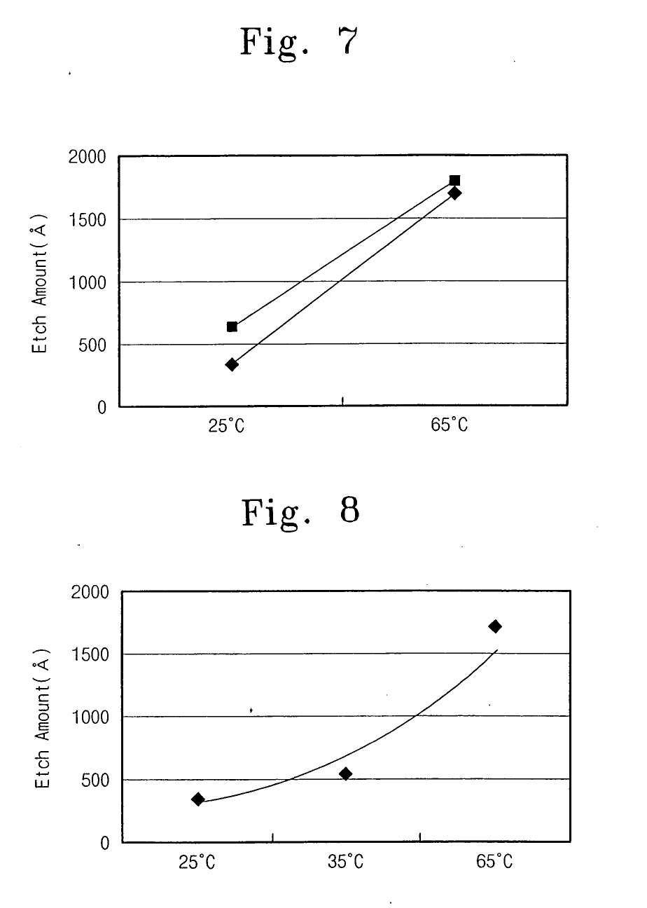

The etching abilities and effectiveness of etching solutions of various compositions according to the various embodiments of this invention were measured. The results of these comparison tests are illustrated in FIGS. 5 to 8. In all of the experiments to be described hereinafter, etching was performed for a period of about five minutes. That is, the wafer on which the SiOC based low-k dielectric layer was formed was dipped into the etching solution for about five minutes. CH₃COOOH oxidant used for the present experiments was diluted with deionized water by 15%, and HF oxidant etchant used for the present experiments was diluted with deionized water by 49%. In embodiments wherein the surfactant was added, the amount of the surfactant was a predetermined % by volume with respect to the total diluted volume of the oxidant and the oxide etchant.

(Experiment 1)

Experiment 1 was performed in order to demonstrate the influence of the surfactant on etching. In the present experiment 1, the etching ratios of two etching solutions in accordance with this invention were compared for their effectiveness in etching the low-k dielectric layer. In a first case, the low-k dielectric layer etching solution (first etching solution) consisted essentially of 90 volume % of CH₃COOOH and 10 volume % of HF each of which was suitably diluted. In a second case, the low-k dielectric layer etching solution (second etching solution) additionally included a surfactant by adding about 0.6 volume % of nonionic surfactant to the first etching solution. The etching ratios were measured respectively at about 25° C. FIG. 5 graphically illustrates the results of experiment 1. Referring to FIG. 5, it can be seen that the etching ratio of the first etching solution (that did not include the surfactant) was about 280 Å/min., while the etching ratio of the second etching solution (that included the surfactant) was about 350 Å/min. Thus, the etching ratio of the second etching solution (that included the surfactant) demonstrated a slightly increased etching ratio in comparison with the first etching solution. As previously described, adding a surfactant to the etching solution increases the moistness ability (wettability) of the low-k dielectric layer.

(Experiment 2)

Experiment 2 was performed in order to compare the etching ability of different etching solutions in accordance with this invention based on the kind of oxidant included in the etching solution. In experiment 2, the etching ratios of an etching solution (third etching solution) including H₂O₂ as oxidant and of an etching solution (fourth etching solution) including CH₃COOOH (PAA) as oxidant were measured and compared. Similar to the conditions used for experiment 1, etching was performed at about 25° C. The third etching solution consisted essentially of 90 volume % of H₂O₂, 10 volume % of HF, each of which was suitable diluted, and 0.6 volume % of surfactant. The fourth etching solution consisted essentially of 90 volume % of PAA, 10 volume % of HF, each of which was suitably diluted, and 0.6 volume % of surfactant, similar to the second etching solution (experiment 1 above). The results of experiment 2 are illustrated in FIG. 6.

Referring to FIG. 6, it can be seen that the etching ratio of the fourth etching solution (with PAA) was about 350 Å/min., while the etching ratio of the third etching solution (with H₂O₂) was only about 40 Å/min. Thus, the fourth etching solution that includes CH₃COOOH as oxidant has a significantly higher etching ability than the etching ability of the third etching solution using H₂O₂ as the oxidant. It is believed that the explanation of this difference is that the oxidation potential of CH₃COOOH is higher than the oxidation potential of H₂O₂.

(Experiment 3)

Experiment 3 was performed in order to demonstrate the influence of the amount of the oxide etchant included in the etching solution, in particular the amount of HF, on the etching results. An etching solution (fifth etching solution) that included 10 volume % of HF was compared with an etching solution (sixth etching solution) that included 20 volume % of HF. The fifth etching solution consisted essentially of 90 volume % of CH₃COOOH, 10 volume % of HF, each of which was suitably diluted, and 0.6 volume % of surfactant, similar to the second etching solution (experiment 1 above). The sixth etching solution consisted essentially of 80 volume % of CH₃COOOH, 20 volume % of HF, each of which was suitably diluted, and 0.6 volume % of surfactant. Experiment 3 was performed both at about 25° C. and at about 65° C. The results of experiment 3 are illustrated in FIG. 78. In FIG. 78, the symbol ♦ (a small hollow square) is used to represent the etching ratio of the fifth etching solution, and the symbol ▪ (a small filled-in square) is used to represent the etching ratio of the sixth etching solution.

Referring to FIG. 78, it is noted that the etching ratio increases as the amount (volume %) of HF increases in the etching solution. At the same time, however, the difference between etching ratios of the two etching solutions does not significantly vary as the etching temperature increases, i.e., the etching ratio of each solution increases with temperature increases at approximately the same rate.

(Experiment 4)

Experiment 4 was performed in order to demonstrate the variation in etching ratio of the etching solutions of this invention in accordance with the treatment temperature. In the experiment 4, the etching ratio of an etching solution (seventh etching solution) that consisted essentially of 90 volume % of CH₃COOOH and 10 volume % of HF, each of which was suitably diluted, was measured at various treatment temperatures. FIG. 87 graphically illustrates the results of experiment 4.

Referring to FIG. 87, it can be seen that the etching ratio increases as the temperature of the etching solution (treatment temperature) increases.

It will be apparent to those skilled in the art that etching solutions of various compositions in accordance with this invention and having proper etching characteristics can be prepared with reference to the results of the above-described various experiments.

As described above, according to the present invention, it is possible to easily remove a low-k dielectric layer from a silicon substrate by means of a single and relatively quick and inexpensive process and, as a result, to re-use expensive wafers used for tests.

While this invention has been particularly shown and described with reference to preferred embodiments thereof, it will be understood by those skilled in the art that various changes in form and details may be made therein without departing from the spirit and scope of the invention as defined by the appended claims. For example, the etching solutions of this invention may also be effectively applied to a process of selectively removing a low-k dielectric layer in semiconductor element fabricating processes. For example, in order to extend trenches formed in a low-k dielectric layer for forming wiring lines, an etching solution in accordance with this invention may be used. In such a case, the width of wiring lines slightly increases such that the resistance of the wiring lines may be reduced.

As described above, according to the present invention, it is possible to easily remove the low-k dielectric layer by means of a single process.

What is claimed is:

1. A dielectric layer etching solution comprising:
an effective proportion of an oxidant effective for oxidizing a low-k dielectric layer; and
an effective proportion of an oxide etchant effective for removing oxides.

2. The dielectric layer etching solution as set forth in claim 1, said solution further comprising an effective proportion of a surfactant selected to improve the wettability of the low-k dielectric layer.

3. The dielectric layer etching solution as set forth in claim 1, wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof.

4. The dielectric layer etching solution as set forth in claim 1, wherein the oxide etchant is selected from the group consisting of HF, HBF₄, NH₄F, and mixtures thereof.

5. The dielectric layer etching solution as set forth in claim 1,
wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof, and also
wherein the oxide etchant is selected from the group consisting of HF, HBF₄, NH₄F, and mixtures thereof.

6. The dielectric layer etching solution as set forth in claim 1,
wherein the dielectric layer etching solution further includes deionized water, and
wherein the dielectric layer etching solution comprises oxidant in the amount of about 30 to about 90 volume %, oxide etchant in the amount of about 0.1 to about 30 volume %, and deionized water in the amount of about 0.1 to about 40 volume %.

7. The dielectric layer etching solution as set forth in claim 6,
wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof, and also
wherein the oxide etchant is selected from the group consisting of HF, HBF₄, NH₄F, and mixtures thereof.

8. The dielectric layer etching solution as set forth in claim 6, further including about 0.05 to about 10% by volume with respect to the total diluted volume of the oxidant and the oxide etchant of a surfactant.

9. The dielectric layer etching solution as set forth in claim 1, wherein the dielectric layer is a silicon oxide layer doped with carbon.

10. A method of etching a low-k dielectric layer using an etching solution as set forth in claim 1, the method comprising the steps of:
providing a wafer on which the low-k dielectric layer is formed; and
contacting the dielectric layer of the wafer with the etching solution.

11. A method of etching a low-k dielectric layer comprising the steps of:
providing a wafer on which at least a low-k dielectric layer is formed; and
contacting the dielectric layer of the wafer with an etching solution that includes at least an oxidant and an oxide etchant.

12. The method as set forth in claim 11, wherein the low-k dielectric layer is a silicon oxide layer doped with carbon.

13. The method as set forth in claim 11, further comprising the step of adding a surfactant to the etching solution to improve the wettability of the low-k dielectric layer.

14. The method as set forth in claim 11, wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof.

15. The method as set forth in claim 11, wherein the oxide etchant is selected from the group consisting of HF, HBF₄, NH₄F, and mixtures thereof.

16. A method of preparing a wafer having a low-k dielectric layer thereon for reuse comprising the step of completely removing the low-k dielectric layer from the wafer using the low-k dielectric layer etching method as set forth in claim 11.

17. A method of etching a low-k dielectric layer on a substrate comprising the steps of oxidizing the low-k dielectric layer to form an oxidized low-k dielectric layer and, substantially simultaneously fluoridating the oxidized low-k dielectric layer into volatile fluorides.

18. The method as set forth in claim 17, wherein the oxidation of the low-k dielectric layer and the fluoridation of the oxidized low-k dielectric layer are performed by a single etching solution.

19. The method as set forth in claim 18, wherein the etching solution comprises:
an oxidant in a proportion effective for oxidizing the low-k dielectric layer; and
an oxide etchant in a proportion effective for fluoridating the oxidized low-k dielectric layer into volatile fluorides to substantially completely remove the low-k dielectric layer from the substrate.

20. The method of etching the low-k dielectric layer as set forth in claim 19,
wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof, and also
wherein the oxide etchant is selected from the group consisting of HF, HBF₄, NH₄F, and mixtures thereof.

21. Low-k dielectric layer etching solution comprising:
an effective proportion of an oxidant for oxidizing a low-k dielectric layer; and
an effective proportion of an oxide etchant for removing oxides,
wherein the volume ratio of the oxidant to the oxide etchant in the etching solution ranges from about 1:1 to about 900:1.

22. The low-k dielectric layer etching solution as set forth in claim 21, wherein the oxidant is selected from the group consisting of H₃PO₄, HNO₃, H₂SO₄, HClO₄, HClO₂, H₂O₂, NaOCl, ClO₂, CH₃COOOH, O₃, and mixtures thereof, and also
wherein the oxide etchant is selected from the group consisting of HF, HBF₄, NH₄F, and mixtures thereof.

23. A low-k dielectric layer etching solution composition comprising:
an oxidant in a proportion of about 30 to about 90 volume % effective for oxidizing a low-k dielectric layer; an oxide etchant in a proportion of about 0.1 to about 30 volume % effective for removing oxides; and
deionized water.
